(19) United States
(12) Patent Application Publication
(10) Pub. No.: US 2025/0147109 A1
(43) Pub. Date: May 8, 2025

(54) METHOD AND SYSTEM FOR MANAGING A BATTERY DEVICE OF AN ELECTRIC OR HYBRID VEHICLE CONTAINING A VOLTAGE MEASUREMENT OF THE CELLS CONNECTED TO AN INTERCONNECTION BAR

(71) Applicants: AMPERE S.A.S., Boulogne Billancourt (FR); NISSAN MOTOR CO., LTD., Kanagawa-ku (JP)

(72) Inventors: Laila GUISSI, Guyancourt Cedex (FR); Rayan HADJ-HAMOU, Guyancourt Cedex (FR); Jana KALAWOUN, Guyancourt Cedex (FR); Nicolas VAFLARD, Guyancourt Cedex (FR)

(73) Assignees: AMPERE S.A.S., Boulogne Billancourt (FR); NISSAN MOTOR CO., LTD., Kanagawa-ku (JP)

(21) Appl. No.: 18/721,286

(22) PCT Filed: Dec. 12, 2022
(86) PCT No.: PCT/EP2022/085463

§ 371 Date: Jan. 14, 2025

(30) Foreign Application Priority Data
Dec. 23, 2021 (FR) 2114312

(51) Int. Cl. G01R 31/388; B60L 58/18; G01R 31/374; G01R 31/396; H02J 7/00

(52) U.S. Cl. CPC G01R 31/388; B60L 58/18; G01R 31/374; G01R 31/396; H02J 7/0013; H02J 7/0048; H02J 7/007182; H02J 7/007194

(57) ABSTRACT

A management system and method enables a more suitable estimation of the voltage of the cells connected to an interconnection bar so as to optimize the durability and operation of the performance of the processing device.

The invention relates to a method and a system for managing an electric battery device. The invention also relates to an electric or hybrid motor vehicle equipped with said system and/or implementing the aforementioned method.

Hybrid or electric motor vehicles are equipped with a battery device, also simply called “battery”, for storing electrical energy, capable of supplying electrical energy to at least one element of an electrical drive train of the vehicle. These battery devices conventionally comprise a plurality of modules connected to each other by busbars, in order to ensure the electrical continuity of the device. Each of these modules comprises a plurality of electrochemical cells, which cells then may or may not be able to be connected to one of the busbars of the device.

During use, the battery devices are controlled and monitored by a dedicated management system, called “Battery Management System”, or “BMS”, so as to monitor and control the state and the operation of the various cells of the battery device as a function of various usage modes such as, for example, charging connected to a distribution network, running discharging or regenerative braking charging. Such a system also allows direct or indirect estimation of the parameters relating to the battery device, such as the state of charge, or “SOC”, the state of health, or “SOH”, and/or any other parameter relating to methods and functions for protecting the battery, for example, safety methods aimed at keeping the device within predefined ranges of values of voltages and/or temperatures in order to ensure durability.

Existing battery management systems have a master-slave structure, which comprises, on the one hand, a master processing unit, remote from the battery device, which notably functions as a control unit and/or a computer, and, on the other hand, a plurality of “slave” elements, comprising voltage and temperature sensors, disposed in the vicinity of the battery device in order to gather data that is then transmitted to the master processing unit.

In current battery devices, each of the various modules is equipped with at least one slave element. When the number of cells of a module is less than the number of measurement channels of a considered slave element, the gathering capacity of said element is not fully exploited, which leads, on the one hand, to underexploitation of the various slave elements and, on the other hand, to an increase in the costs and the mass of the battery device due to the significant number of slave elements required to equip all the modules of the device.

In order to address such a problem, it is known, for example, as disclosed in Chinese application CN 107482699, for an architecture of the battery device to be implemented in which the same slave element is used to gather data from two distinct modules, with some of the measurement channels being dedicated to a first module, while the remaining channels are dedicated to a second module. Such an architecture advantageously allows the various slave elements to be used at their full capacity, thus reducing the number of slave elements. The known management systems are nevertheless unsuitable for such an architecture. Indeed, the voltage measurements taken by the slave elements on the cells fitted with a busbar are biased by the presence thereof. The measured voltage includes an additional voltage specific to the busbar that, depending on the usage mode of the battery device, results in overestimation or underestimation of the voltages. Consequently, the estimates of the aforementioned parameters, such as SOH or SOC, are based on voltage values that may be erroneous and any safe operating method of the battery device using these voltage values may be triggered inappropriately.

The invention falls within this context and aims to provide a method and a system for managing the battery device that overcomes the aforementioned disadvantages. In particular, the invention aims to provide a refined estimate of the voltage values of the various cells in order to optimize the operating conditions and the durability of the battery device.

The invention relates to a method for managing an electric battery device comprising a plurality of modules mounted in series, each comprising a plurality of cells mounted in series, each module being directly electrically connected to at least one other module of the plurality of modules so as to form a pair of modules, with this connection being made by means of a busbar connected at a cell of each of the modules of the pair. The management method comprises:
a step of measuring a voltage specific to each cell, whether or not it is connected to a busbar, by means of slave elements, and a step of measuring the temperature of each module, with each temperature measurement being associated with the one or more busbars connected to the considered module, each slave element comprising a plurality of measurement channels and being connected to the two modules of the considered pair:
a step of measuring a current flowing through the battery device;
a step of transmitting the measurements to a processing unit remote from the battery device;
a step of estimating a voltage compensation value specific to each cell connected to a busbar, the compensation value corresponding to an estimated voltage of the considered busbar for each of said cells, with the compensation value being estimated as a function of the temperature and of the current of the module comprising the considered cell;
a step of estimating a corrected voltage value specific to each of the cells connected to a busbar by compensating the measured voltage value with the estimated compensation value;
a step of adjusting and/or determining at least one limiting and/or state parameter of the operation of the battery device as a function of the estimated corrected voltage and/or as a function of the measured voltage.

Notably, the compensation value can depend on an estimated resistance of the busbar connected to the considered cell.

Notably, the step of determining at least one limiting parameter and/or at least one state parameter can comprise:
a sub-step of determining a maximum voltage value specific to a cell from among a set formed by the measured voltage values, for the cells that are not connected to a busbar, and the estimated corrected voltages, for the cells that are connected to at least one busbar; and
a sub-step of determining, as a function of the maximum voltage value, a charging power that can be allocated to the battery device when it is in a charging mode, with the charging power being limited when the maximum voltage value is greater than or equal to a maximum charging voltage threshold; and/or
a sub-step of determining, as a function of the maximum voltage value, a regenerative charging power that can be allocated to the battery device when it is in a regenerative charging state, with the regenerative charging power being limited when the maximum voltage value is greater than or equal to a maximum regenerative charging voltage threshold.

The method can further comprise a step of determining a usage mode of the electric battery device from among a charging, discharging or regenerative charging mode, the method executing, when a charging mode is detected, a step of regulating the charging power comprising:
a sub-step of computing a variation in the charging power between the charging powers respectively observed between two instants tₙ₋₁ and tₙ;
a sub-step of estimating a charging power to be implemented at a future instant tₙ₊₁, and a sub-step of detecting a future increase in the charging power with respect to the previously computed power variation and to the charging power observed at the instant tₙ;
a step of limiting the future charging power such that, at the instant tₙ₊₁, the charging power is limited so as to be less than or equal to the charging power implemented at the instant tₙ, with the limitation of the charging power being lifted when a temperature variation of at least one module is detected as being greater than a predetermined temperature threshold between the instants tₙ₋₁ and tₙ.

The step of determining at least one limiting parameter and/or at least one state parameter can comprise:
a sub-step of determining a minimum voltage value of a cell from among a set comprising the measured voltage values, for the cells that are not connected to a busbar, and from among the estimated corrected voltages, for the cells that are connected to a busbar;
a sub-step of determining a discharging power of the battery device as a function of the minimum voltage value, with the discharging power being limited when the minimum voltage value is less than or equal to a minimum discharging voltage threshold.

The step of determining at least one limiting parameter and/or at least one parameter can comprise:
a sub-step of estimating a resistance of each cell connected to a busbar at an instant tₓ, comprising computing an average resistance of the cells of the battery device that are not connected to a busbar as a function of the voltages measured for these cells and assigning the value of such an average to each cell connected to a busbar;
a sub-step of determining a discharging power that can be allocated to the battery device when the minimum voltage value is greater than the minimum discharging voltage threshold, with the discharging power being determined as a function of the resistances of the various cells and of the measured temperature for each module.

The step of determining at least one limiting parameter and/or at least one parameter can comprise a sub-step of estimating a state of charge of the various cells of the battery device:
with the state of charge of the cells that are not connected to a busbar being defined as a function of the measured voltage and of the current that are specific thereto,
with the state of charge of the cells that are connected to a busbar being defined as a function of the current specific thereto.

The invention also relates to a system for managing an electric battery device comprising a plurality of modules each comprising a plurality of cells, with each module being directly electrically connected to at least one other module of the plurality of modules so as to form a pair of modules, with this connection being made by means of a busbar connected at a cell of each of the modules of the pair, with the various modules being electrically connected to each other, the system comprising hardware and/or software elements implementing the management method according to the invention, the hardware elements comprising at least one slave element capable of taking temperature and voltage measurements connected to each of the modules of the pair, a processing unit capable of receiving measurements from the at least one slave element, a memory unit and at least one current sensor.

The invention also extends to a hybrid or electric motor vehicle comprising at least one electric battery device comprising a plurality of modules each comprising a plurality of cells, with each module being electrically connected to each of the other modules of the plurality of modules by means of a busbar in the vicinity of at least one cell, with the vehicle further being equipped with a management system according to the preceding claim.

The invention also relates to a computer program product comprising program code instructions stored on a computer-readable medium for implementing the steps of the management method according to the invention when said program operates on a computer. Alternatively, such a computer program product can be downloaded from a communication network and/or stored on a computer-readable data medium and/or can be executed by a computer, with such a program product comprising instructions which, when the program is executed by the computer, cause the computer to implement the method disclosed above.

The invention also relates to a computer-readable data storage medium, which stores a computer program comprising program code instructions for implementing the method according to the invention or a computer-readable storage medium comprising instructions which, when they are executed by a computer, cause the computer to implement the safety method.

Finally, the invention relates to a signal of a data medium conveying the computer program product as disclosed above.

Further details, features and advantages will become more clearly apparent upon reading the following detailed description, which is provided by way of a non-limiting indication, in relation to the various exemplary embodiments illustrated in the following figures, in which:

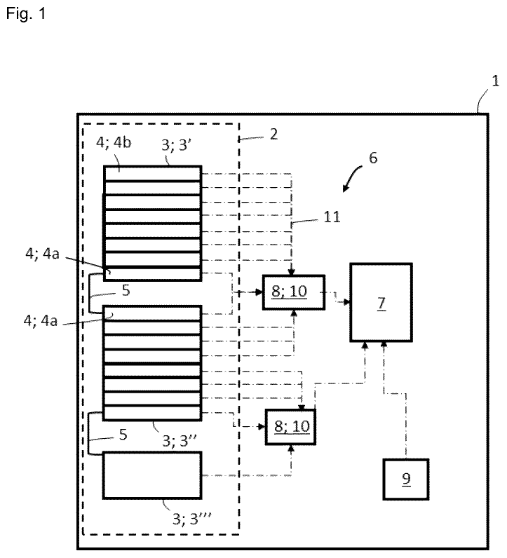

FIG. 1 schematically shows an embodiment of a vehicle equipped with a system for managing a battery device;

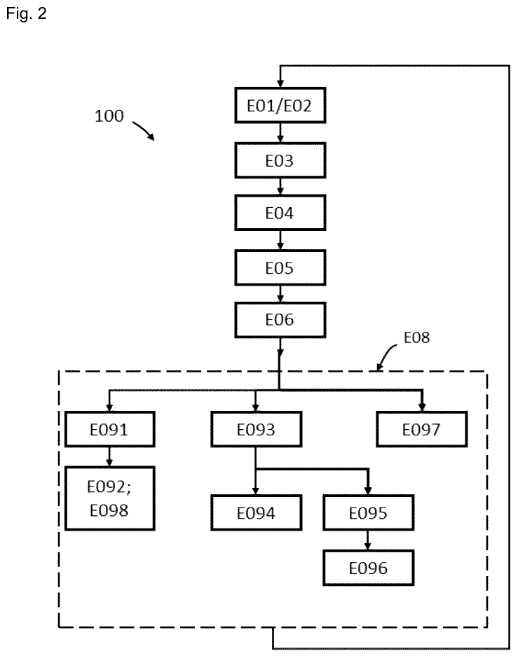

FIG. 2 is a flowchart of an exemplary embodiment of a method for managing the battery device;

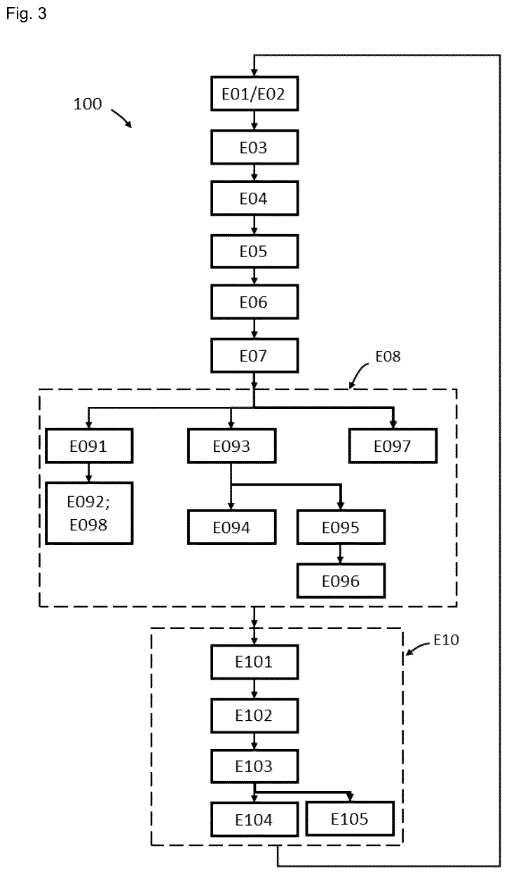

FIG. 3 is a flowchart of a particular exemplary embodiment of the method of the battery device illustrated in FIG. 2.

FIG. 1 schematically illustrates an electric or hybrid motor vehicle 1. The vehicle 1 can be of any type, i.e., it can be a passenger vehicle, a utility vehicle, a truck or a bus. Furthermore, the vehicle 1 can be an autonomous or non-autonomous vehicle.

The vehicle 1 is equipped with an electric battery device 2, also called “battery”, “electrical energy storage device”, or even “battery pack”, configured to supply one or more elements of an electrical drive train of the vehicle 1, not shown, with electrical energy. For example, it can supply an electric motor.

The battery device 2 comprises a plurality of modules 3 electrically mounted in series. Each module 3 comprises a plurality of electrochemical cells 4 mounted in series within the same module. The various modules 3 are electrically connected to each other by means of busbars 5, which, for example, can be made of copper. Each module is directly electrically connected to at least one other module of the plurality of modules 3, notably an adjacent module within the battery device 2, so as to form a pair of modules 3. The term “directly connected” is understood to mean that these modules 3 are connected to each other by a single busbar 5, without another busbar or another module being electrically interposed between them.

Thus, a battery device 2 comprising a number k of modules 3 can, in a non-limiting manner, include a number k−1 of busbars 5 allowing successive or adjacent modules 3 to be connected to each other. Each module of the device thus comprises at least one cell 4a connected to a busbar 5, and at least one cell 4b not connected to such a bar. For the sake of clarity in the illustrated example, only two distinct modules 3 forming a pair and each comprising eight cells 4 are shown. It is understood that such a depiction is by no means limiting and that the device can include more modules 3 and/or a different number of cells 4.

The vehicle 1 is also equipped with a system 6 for managing the battery device 2. The management system 6 comprises hardware and/or software elements implementing a management method 100 as disclosed hereafter. The hardware elements comprise a processing unit 7 and one or more slave elements 8 comprising a plurality of temperature and voltage measurement channels. The system can further comprise a memory unit 9 and at least one current sensor 10 for the current flowing through the battery device 2.

The management system 6 is organized in accordance with a “master-slave” architecture, in which the processing unit 7, also called master processing unit 7, is remote from the battery device 2 and is configured to receive the data from the various “slave” elements 8, particularly comprising voltage and temperature sensors, in order to carry out the processing.

The processing unit 7 comprises at least one computer comprising hardware and software resources, more specifically at least one processor, or microprocessor. The processing unit 7 cooperates with the memory unit 9, the slave elements 8 and the sensor 10 and assumes the “master” function in the architecture of the management system 6. The processing unit 7 is capable of executing instructions for implementing a computer program.

The management system 6 comprises a plurality of voltage and temperature sensors 8 arranged in the vicinity of the modules 3 of the battery device 2. Such sensors function as “slave” elements within the system. Each slave element 8 comprises a plurality of measurement channels 11. In particular, each of the one or more slave elements 8 comprises a greater number of channels than the number of cells 4 included in each module 3 of the battery device 2. Within the system according to the invention, each slave element 8 is configured so as to be able to take measurements on two distinct modules 3 of the plurality of modules 3, notably on the modules 3 of a considered pair, as disclosed above. In this case, a first slave element 8, comprising at least one voltage and temperature sensor, comprises twelve channels, with eight being dedicated to the eight cells 4 of a first module 3′ of the pair, while the remaining four are connected to four cells 4 of a second module 3″ of the pair, distinct from the first module 3′. A similar second slave element 8, which is partially shown, is connected to the remaining four cells 4 of the second module 3″, while the other eight channels are connected to a third module 3′″. It is also understood that said second module 3″ is connected to said third module by means of a busbar 5, with the second module and the third module thus forming a pair connected by a busbar 5 that is specific thereto. According to one non-limiting exemplary embodiment, a last cell 4 of the first module 3′ is connected to a busbar, which itself is connected to a first cell 4 of the second module 3″. The term “first” and “last” is understood herein to mean the first cell and the last cell within the in-series electrical assembly of the considered module. Similarly, a last cell 4 of the second module 3″ is connected to a first cell 4 of the third module 3′″. Such a principle is reproduced, mutatis mutandis, for all the modules 3 of the battery device 2.

Due to the measurement continuity, it is known that, when a slave element is used to manage two distinct battery modules 3, the voltage measurement taken from a cell connected to at least one busbar 5 includes an additional voltage corresponding to the voltage specific to said busbar 5. This is notably the case of the “last cell” 4, as disclosed above. This results in an erroneous measurement of the voltage of the cells 4a connected to a busbar. Indeed, the busbar 5 has higher resistance, which leads to a voltage difference between the two battery cells 4a connected to the two ends of said bar. The additional voltage of the busbar 5, as disclosed further hereafter, depends on its resistance, which can be subject to variation according to:
the size and the composition of the busbar 5;
the contact and clamping quality between the module and the busbar;
the temperature of the busbar 5; and
the state of aging of the surface of the busbar 5.

The size of the additional voltage due to the busbar 5, in other words, the difference between the measured voltage and the actual voltage of a cell 4a connected to said bar, affects the operation of the battery device 2 in its various usage or operating modes. For example, when charging the battery device 2, such an additional voltage induces an overestimation of the measured voltage relative to the cells 4 that are not connected to at least one busbar 5. Conversely, an underestimation of this voltage is observed when discharging the device. In particular, in the case of charging, the greater the currents used, for example, in the case of “Fast Charging” or “Ultra-Fast Charging”), the higher the additional voltage.

These erroneous measurements of the voltage of the cells 4a that are connected to at least one busbar 5 also affect various parameters relating to the battery device 2, such as the power, its state of charge or its state of health, as disclosed above, and influence the operation of various systems regulating the use of the battery device 2 on the basis of such parameters, as disclosed further hereafter with reference to the method, which affects harnessing of the performance capability of the battery device 2.

In this sense, one embodiment of a management method 100 that allows more exact estimation of these voltages, as well as of various parameters relating to the battery device 2, is described hereafter with reference to FIGS. 2 and 3.

In general, the management method 100 initially comprises a step E01 of measuring a voltage V_{m_cell} specific to each cell of the battery device 2. These measurements are taken by means of the slave elements 8. As disclosed above, each slave element 8 comprises a plurality of measurement channels 11 and is connected to at least two distinct modules 3. The number of measurement channels of a considered sensor is notably greater than the number of cells 4 specific to the modules 3 to which it is connected.

The method also comprises a step E02 of measuring the temperature T_{mod} of each module 3 of the battery device 2. Each temperature measurement T_{mod} of a module 3 is then associated with the one or more busbars 5 connected to the considered module 3 in order to allow, as disclosed further hereafter, an estimate of the temperature of the busbar 5 based on the heating-up of the module. Notably, for each considered busbar 5, the associated measured temperature T_{mod} is that which is specific to the module of the pair of modules 3 that it connects comprising the cell with the erroneous voltage due to the presence of said busbar 5. In this case, in the example disclosed above, each busbar 5 is associated with the measured temperature T_{mod} specific to the module 3 of the pair comprising the last cell 4 in the in-series electrical assembly. With respect to the illustrated modules, in the pair formed by the first module 3′ and the second module 3″, the busbar 5 is associated with the temperature of the first module 3′.

The voltage V_{m_cell} and temperature T_{mod} measurements can be taken in real time, i.e., continuously, or, alternatively, at a preprogrammed, regular time interval. The temperature and voltage measurements can be taken simultaneously or successively relative to each other.

The management system 6 also executes a step E03 of measuring a current Iₘ flowing through the battery device 2 by means of the one or more current sensors 10. The current is evaluated relative to the scale of the battery device 2.

As for the voltage V_{m_cell} and temperature T_{mod} measurements, the current Iₘ can be measured in real time, or, alternatively, at a preprogrammed, regular time interval. The current also can be measured simultaneously or successively relative to the temperature and/or voltage measurements.

The system then comprises a step E04 of transmitting the voltage V_{m_cell} and temperature T_{mod} measurements taken by the slave elements 8 to the remote processing unit 7. The same applies to the current measurements Iₘ.

The processing unit 7 then executes a step E05 of estimating a voltage compensation value V_{b_est} specific to each cell 4a connected to a busbar 5. Such a compensation value V_{b_est} corresponds to an estimated voltage specific to a considered busbar 5 for each of said cells 4a. The compensation value is estimated by means of the current Iₘ and an estimate of the resistance Rₑₛₜ of the busbar 5 connected to the cell 4a, notably obtained as a function of the measured temperature T_{mod} of the module 3 comprising the considered cell, with the temperature of the busbar 5 not being able to be measured directly. The voltage compensation value V_{b_est} specific to each cell 4a connected to a busbar 5 in this case corresponds to the product of the current Iₘ and of the estimate of the resistance Rₑₛₜ of the busbar connected to the considered cell 4a.

It is thus advantageously possible to take into account a variation in the behavior of the cells 4 of the same module 3, notably a variation in the behavior of the one or more cells 4a connected to one or more busbars 5 relative to cells 4b not connected to a busbar 5.

The estimated resistance Rₑₛₜ particularly can be defined as follows:

$${R}_{est} = {R}_{ref} \times ( 1 + {α}_{1} \times ( {T}_{mod} - {T}_{ref} ) ) + {R}_{cont} \times ( 1 + {α}_{2} \times ( {T}_{mod} - {T}_{ref} ) ) \qquad ( 1 )$$

where.
Rₑₛₜ is the estimated value of the resistance of the busbar 5. T_{ref} is a fixed reference temperature value. In this case, in a non-limiting manner, this temperature is 20° C. R_{ref} is a fixed value for estimating the resistance of the busbar 5 at the reference temperature T_{ref}. This value can be defined or calibrated beforehand and stored on the memory unit 9. It is determined according to the dimensions of the busbar 5, with the resistance thereof increasing with its size, and according to its composition. T_{mod} is the measured temperature of the module to which the considered busbar 5 is connected. The difference between the measured temperature T_{mod} and the reference temperature T_{ref} thus represents heating-up, for example, due to the use or the charging thereof, of the battery device 2. R_{cont} is an estimated fixed value of the contact resistance that exists between the considered module and the busbar 5 connected thereto. This value can be defined or calibrated beforehand and stored on the memory unit 9. The contact resistance R_{cont} is defined as a function of the quality of the contact and of the clamping between the busbar 5 and the considered module, α₁ is a fixed value representing the increase in the reference resistance R_{ref} as a function of the temperature. In particular, α₁ is the guiding coefficient of a straight line representing the evolution of the reference resistance as a function of the temperature, calibrated beforehand. α₂ is a fixed value representing the increase in the contact resistance R_{cont} as a function of the temperature. Similarly to α₁, this is the guiding coefficient of a straight line representing the evolution of the contact resistance as a function of the temperature, calibrated beforehand. The values a, and α₂ are defined before executing the method, notably before assembling the vehicle, and are stored on the memory unit 9 so as to be accessible to the processing unit 7.

As disclosed above, the resistance Rₑₛₜ of the busbar 5 varies according to parameters such as its size, its composition, the quality of the contact and the clamping between the module and the busbar, the temperature of the busbar 5 or even the state of aging of the surface of the busbar 5. The equation disclosed above allows the resistance specific to the considered busbar 5 to be estimated, and consequently allows the resulting additional voltage to be estimated by a simple multiplication with the measured current value. The completed estimate thus takes into account these parameters in order to carry out a low estimate of the voltage value so as to fully or partly correct any positive excess in the case of a charging current or negative excess in the case of a discharging current of measured voltage due to the considered busbar 5. Indeed, it is essential that the compensation value is not overestimated at the risk of generating overvoltage or undervoltage situations, as disclosed further hereafter, that can affect the durability of the various cells 4.

The management system 6 can thus obtain an estimate E06 of a corrected voltage value V_{corr} specific to each of the cells 4 connected to a busbar 5. The estimated corrected voltage corresponds to the measured voltage of the corrected cell so as to ignore the additional voltage specific to the busbar 5. Such a voltage advantageously is more representative of the actual situation, i.e., of the real voltage, of the considered cell 4 than the measured voltage V_{m_cell}. The estimated corrected voltage V_{corr} of the cell is defined as follows:

$${V}_{corr} = {V}_{m \_ cell} - {R}_{est} \times {I}_{m} = {V}_{cell} - {V}_{b \_ est} \qquad ( 2 )$$

where:
Rₑₛₜ is the estimated value of the resistance of the busbar 5 previously computed for the cells 4a connected to a busbar 5. It should be noted that the value Rₑₛₜ is zero for the cells 4b that are not connected to a busbar 5. V_{m_cell} is the voltage of the cell measured beforehand and Iₘ is the measured current.

Optionally, as shown in FIG. 3, the system can execute, at the same time as or after the previously disclosed steps, a step E07 of determining a usage mode of the electric battery device 2 from among a charging, discharging or regenerative charging mode. The term “discharging” is understood to mean, for example, that the vehicle 1 is in a running phase. The term “regenerative charging” is understood to mean recovering electrical energy resulting from the vehicle 1 braking. For example, the processing unit 7 receives a signal indicating the usage mode of the battery device 2 at an instant t at which the method according to the invention is implemented.

The management system 6 then implements a step E08 of adjusting and/or determining at least one limiting parameter of the operation of the battery device 2 and/or at least one parameter for evaluating a state of said battery device as a function of the determined corrected voltage V_{corr} and/or as a function of the measured voltage V_{m_cell}. Notably, such a parameter can be directly or indirectly connected to one of the usage modes of the battery device 2. Such a step can, in particular, correspond to the adjustment or to the updating of an existing value of the considered parameter, for example, resulting from a prior cycle of executing the method according to the invention and previously stored on the memory unit 9 or any other memory element of the vehicle 1.

FIGS. 2 and 3 illustrate the determination E08 of parameters relating to the “charging” or “regenerative charging” modes. The “charging” mode can equally relate to a normal charging situation and to a fast charging or ultra-fast charging situation.

Conventionally, during charging or regenerative charging phases, safety methods make it possible to limit, i.e., to reduce, an allocated charging power relative to the maximum capacity. These safety methods, also known as “derating” methods, are implemented in order to maintain the temperature and/or the voltage of the various cells 4 within predetermined adapted value ranges. Such methods are intended to avoid overvoltage or overheating situations, notably in order to ensure the durability of the battery device 2. These methods therefore allow a charging power P_{c}, or a regenerative charging power P_{c_regen}, to be adapted, as a function of the measured voltage V_{m_cell} of the cells 4, with said power being limited as soon as the voltage of a cell is greater than or equal to a predetermined maximum voltage threshold, specific to the considered state of charge.

The charging power P_{c}, or regenerative charging power P_{c_regen}, thus can be defined based on a 2D map as a function of the temperature T_{mod} and of the measured voltage V_{m_cell} under normal conditions, i.e., when the measured temperatures and voltages are within the accepted value ranges, and, when the measured voltage V_{m_cell} is greater than the maximum voltage threshold, the power is reduced. In the case of an architecture of the battery device 2 as disclosed above, the voltage measurements V_{m_cell} of the cells 4 connected to a busbar 5 are erroneous. In particular, in the case of a charging or regenerative charging mode, the measured voltages V_{m_cell} are overestimated with respect to the actual voltage value of the considered cell, with the size of such an overestimate varying as a function of the considered busbar. Consequently, the safety methods, limiting the charging P_{c} or regenerative charging P_{c_regen} power are triggered earlier than necessary, while the actual voltage of the cell is within the acceptable value range, due to the additional voltage of the busbar 5 included in this measurement. This increases the required charging time, but also unjustifiably limits the performance capabilities of the vehicle.

Within the context of the present invention, the method 100 allows such disadvantages to be limited on the basis of the determination of the charging power P_{c} or of the regenerative charging power P_{c_regen} based on the corrected estimated voltage V_{corr}, which is more representative of reality, rather than on the basis of the measured voltage V_{m_cell}.

In this sense, the step E08 of adjusting and/or determining at least one parameter relating to the battery device 2 can initially comprise a sub-step E091 of determining a maximum voltage value within the battery device 2 by means of the processing unit 7. Such a maximum value is determined from among a set formed by the measured voltage values V_{m_cell}, for the cells 4b that are not connected to a busbar 5, and by the estimated corrected voltages V_{corr} as computed beforehand, for the cells 4a connected to a busbar 5.

In particular, such a sub-step can be defined as follows:

$${V}_{max} = Max {\{ {V}_{m \_ cell} - {R}_{est} \times {I}_{m} \}}_{i = 1}^{nbr \_ cell} \qquad ( 3 )$$

where:
Vₘₐₓ is the maximum voltage determined relative to the scale of the battery device 2. V_{m_cell} is the voltage measured for each cell, whether or not it is connected to a busbar 5. Rₑₛₜ is the estimated resistance of the previously computed considered busbar 5, with such a value being zero in the case of the cells 4b that are not connected to a busbar 5. Iₘ is the current flowing through the battery device 2, with the product of the estimated resistance and of the current defining, as described above, an estimated value of the additional voltage specific to the busbar 5. nbr_cell is the number of cells 4 included in the entire battery device 2.

The method 100 can then comprise a sub-step E092 of determining, as a function of the defined maximum voltage value Vₘₐₓ, a charging power P_{c} in anticipation of the execution of a charging mode, or, alternatively, for a charging mode implemented when executing the method according to the invention. The processing unit 7 compares the defined maximum voltage value Vₘₐₓ with a maximum authorized charging voltage threshold S_{c_max}. If the determined maximum voltage value Vₘₐₓ is greater than or equal to said threshold, then the allocated charging power P_{c} is limited, notably according to safety methods, also referred to as “derating” methods.

If the computed maximum voltage value Vₘₐₓ is less than said threshold, the processing unit 7 of the management system 6, or, alternatively, any other processing module equipping the vehicle 1 and communicating with the processing unit 7, can define a charging power P_{c} that can be allocated to the battery device 2 when it is in the charging mode. In other words, the processing unit 7 can define the adapted charging power P_{c} when the maximum voltage Vₘₐₓ is within a previously defined range of accepted voltage values, lower than the maximum charging voltage threshold. A similar principle applies, mutatis mutandis, to the regenerative charging power for the regenerative charging mode.

By way of a non-limiting example, the charging power P_{c} can be defined as a function of the computed maximum voltage Vₘₐₓ and of the measured temperature T_{mod} of the module based on a 2D map stored on the processing unit and specific to the usage mode of the considered battery device 2. According to a particular example, a minimum temperature and a maximum temperature are extracted from among the temperatures T_{mod} of the various modules measured beforehand, then are used in order to define two charging powers P_{c} in the aforementioned 2D map. The lowest power from among these two powers then can be applied as the charging power P_{c}.

According to a particular embodiment, illustrated in FIG. 3, the method also can be configured so as to limit, or even prevent, situations generating oscillations of the voltage and of the power when the charging mode is implemented. Indeed, it is known that the less a cell is charged, the lower the voltage and the greater the allocated charging power. When the cells 4 begin to charge, the voltage increases and the power allocated to charging decreases. Consequently, such a drop in charging power causes a drop in the measured voltage, including the additional voltage of the busbar 5 at the cells 4a connected to such a bar. The charging power is then increased, which results in a new increase in the voltage. Such a sequence is repeated and a phenomenon of voltage oscillation then can be observed, which can assume non-negligible values of several tens of kilowatts.

In order to overcome the aforementioned disadvantages, when a charging mode is detected in step E07, i.e., that such a mode is being executed, the method and the system according to the invention advantageously can be configured in order to limit the possibility of increasing the charging power when said power has been reduced beforehand. In this sense, the method can comprise, for a device in the state of charge, a step E10 of regulating the charging power comprising:
a sub-step E101 of computing a variation ΔP_{c1} in the observed charging power P_{c_n-1}, P_{c_n} between a past instant tₙ₋₁ and a present instant tₙ;
a sub-step E102 of estimating a charging power P_{c_n+1} to be implemented at a future instant tₙ₊₁, and a sub-step E103 of detecting a future increase in the charging power with respect to the previously computed power variation ΔP_{c1} and to the charging power P_{c_n} observed at the instant tₙ. Such an estimate can be carried out, by way of an example, based on a 2D map, as disclosed above;
a sub-step E104 of limiting the future charging power P_{c_n+1} such that, at the instant tₙ₊₁, the charging power is limited so as to be less than or equal to the charging power P_{c_n} implemented at the instant tₙ.

The method according to the invention is also particularly configured so that the limitation of the charging power can be lifted when a temperature variation ΔTₘ is detected E105 in at least one module T_{mod} of the battery device 2 that is greater than a threshold Tₛ between the instants tₙ₋₁ and tₙ. Indeed, it is also known that the increase in charging power can result from heating-up of the battery device 2 that is conventionally observed due to the flow of current through the cells 4. The method thus comprises a sub-step, not shown, of computing a temperature variation ΔTₘ in at least one module T_{mod} between the instants tₙ₋₁ and tₙ specific to the various modules, with such a computation being carried out by the processing unit 7 on the basis of the measurements taken by the slave elements 8 of the battery device 2. The method then comprises a sub-step of comparing these various values with the threshold Tₛ. By way of a non-limiting example, such a threshold can range between 1 and 5° C. When the variation ΔTₘ is less than the threshold Tₛ, the estimated future power increase is due to the voltage variation and not to the temperature. The charging power P_{c} is limited so as to be less than or equal to that implemented at the instant tₙ. Conversely, if the temperature variation ΔTₘ is greater than said threshold, the estimated future power increase is at least partly due to a variation in the temperature of the battery device 2. The charging power P_{c} can therefore increase. Possible oscillations then can be generated but these have lower values compared to those observed due to a voltage variation.

FIGS. 2 and 3 also illustrate the determination of parameters relating to the discharging mode of the battery device 2, for example, when running the vehicle 1. As disclosed with reference to the state of charge, vehicles conventionally implement, when discharging the battery device 2, safety methods, or “derating” methods, in order to maintain the temperature and/or the voltage of the various cells 4 within suitable value ranges, in particular in this case in order to prevent undervoltage situations. Such safety methods allow a discharging power to be adapted, as distinct from the previously disclosed charging power P_{c}, as a function of the voltage of the cells 4 in order to limit, i.e., to reduce, the discharging power as soon as the voltage of a cell is less than or equal to a predetermined minimum voltage threshold, specific to the discharging mode of the battery device 2. As disclosed above, it follows that, when the measurements of the voltage of the cells 4a connected to a busbar 5 are erroneous due to the voltage of the busbar 5, these safety methods are triggered earlier than necessary, even though the actual voltage of the cell is within the acceptable value range.

The method 100 according to the invention allows such disadvantages to be limited by determining the discharging power P_{de} on the basis of the estimated corrected voltage rather than on the basis of the measured voltage V_{m_cell}, notably within the context of such safety methods. The step E08 of adjusting and/or determining at least one limiting parameter and/or at least one state parameter can thus include a sub-step E093 of determining a minimum voltage value Vₘᵢₙ from among the various voltage values of the cells 4 of the battery device 2. The minimum value Vₘᵢₙ is defined from among a set of values made up of the measured voltages V_{m_cell} of the cells 4a that are not connected to a busbar 5 and of the estimated corrected voltages V_{corr} for the cells 4a connected to a busbar 5.

In particular, the minimum voltage value is defined as follows:

$${V}_{min} = Min {\{ {V}_{m \_ cell} - {R}_{est} \times {I}_{m} \}}_{i = 1}^{nbr \_ cell} \qquad ( 4 )$$

where:
Rₑₛₜ is the previously estimated resistance of the considered busbar 5, with such a value Rₑₛₜ being zero in the case of the cells 4b that are not connected to a busbar 5. V_{cell} is the measured voltage for each cell, whether or not it is connected to a busbar 5. Iₘ is the current flowing through the battery device 2. nbr_cell is the number of cells 4 included in the entire battery device 2.

The method can then include a sub-step E094 of determining, as a function of the minimum voltage value Vₘᵢₙ, a discharging power P_{de} suitable for implementing a discharging mode, which is in progress or will be executed subsequently. The processing unit 7 compares the determined minimum voltage value Vₘᵢₙ with the minimum authorized discharging voltage threshold S_{d_min}.

If the determined minimum voltage value Vₘᵢₙ is greater than the minimum authorized discharging voltage threshold S_{d_min}, i.e., the minimum voltage within the battery device 2 is within the authorized range of voltage values and the safety methods are not necessary, the processing unit 7 of the management system 6, or, alternatively, any other processing module equipping the vehicle 1, can define, in a known manner, a discharging power P_{de} that can be allocated to the battery device 2 on the basis of a 2D map depending on the state of charge, or SOC, of the battery device 2, and on the temperature. In particular, the principle for defining a power as a function of a minimum temperature and of a maximum temperature, as disclosed above with reference to the charging power P_{c}, applies mutatis mutandis.

If the minimum voltage value Vₘᵢₙ is less than or equal to said threshold, then the allocated discharging power S_{d_min} is limited relative to the maximum capacity. In other words, triggering existing safety methods takes into account the estimated voltage V_{corr} of the cells 4a so that they are implemented at voltage values that are more representative of the real voltage of the cells 4 of the battery device 2. The discharging power P_{de} is then defined as a function of the temperature and of the resistance of the cells 4, which itself is based on the measured voltage V_{m_cell}. As a result, the method according to the invention provides a more suitable evaluation of the estimated resistances taking into account the additional voltage of the various busbars 5 and, consequently, provides a better evaluation of the discharging powers P_{de}. Such a principle will hold all the more true as the cells 4 age, with their resistance, and therefore the resistance specific to the busbars 5, then increasing. In this sense, the step E08 of adjusting and/or determining at least one parameter of the operation of the battery device 2 can include a sub-step E095 of estimating a resistance R_{d_est} specific to each cell 4a connected to a busbar 5 at an instant tₓ. Such a resistance R_{d_est} is estimated by computing an average resistance Rₘ of the cells 4b of the battery device 2 that are not connected to a busbar 5, with the resistance of said cells being computed as a function of the measured voltages V_{m_cell} and of the current Iₘ.

The value of this average resistance Rₘ is then assigned to each of the cells 4a connected to a busbar 5. The processing unit 7 can then execute a step E096 of determining a discharging power P_{de} of the battery device 2 as a function of the resistances of the various cells 4a, 4b that may or may not be connected to a busbar 5, and of the temperature T_{mod} measured for each module 3. By way of a non-limiting example, the discharging power P_{de} is defined, as disclosed above, on the basis of a 2D map as a function of the temperature of the modules and/or of the battery device, of the state of charge of the battery device 2 and of a maximum resistance value, with said maximum value being determined from among the estimated resistances in the case of cells 4a that are connected to a busbar 5 and the resistances computed on the basis of the measured voltage V_{m_cell} and of the current Iₘ in the case of cells 4b that are not connected to a busbar 5.

The resistance values R_{d_est} thus obtained for the cells 4a connected to busbars 5 are more representative of reality and prevent the inclusion of the additional voltage, and in this case the resistance, specific to the busbars 5. Such a method in this case is suitable because, relative to the scale of the battery device 2, the number of cells 4a connected to a busbar 5 is strictly less than the number of cells 4b not connected to a busbar.

The step E08 of adjusting and/or determining at least one parameter of the operation of the battery device 2 can also include a sub-step E098 of determining a regenerative charging power P_{c_regen}. As disclosed with reference to the charging and discharging modes, the vehicle also can be configured in order to execute, during the regenerative charging phases, safety, or “derating”, methods, in order to maintain the temperature and/or the voltage of the various cells 4 within appropriate value ranges.

In this case, these safety methods allow the regenerative charging power P_{c_regen} to be adapted in order to limit it, i.e., to reduce it, as soon as the voltage of a cell is greater than or equal to the maximum authorized regenerative charging voltage threshold S_{regen_max}. It should be noted that such a threshold S_{regen_max} can have a value identical to or distinct from that of the maximum charging voltage threshold S_{c_max}.

If the computed maximum voltage value Vₘₐₓ, notably computed according to the formula (3) disclosed above with reference to the charging mode, is lower than said threshold, i.e., the maximum voltage value Vₘₐₓ is within the normal value range, the processing unit 7 of the management system 6, or, alternatively, any other processing module, can define a charging power P_{c_regen} that can be allocated to the battery device 2 as a function of a 2D map. The preceding description that is provided with reference to the discharging mode applies, mutatis mutandis, to the considered 2D map, which can, by way of a non-limiting example, be defined as a function of the temperature of the modules and/or of the battery device, of the state of charge and of a maximum resistance value, as disclosed above.

If the determined maximum voltage value Vₘₐₓ is greater than or equal to the threshold S_{regen_max}, i.e., when the safety, or “derating”, methods must be executed, then the regenerative charging power P_{c_regen} is limited.

As disclosed above, the resistance of the cells 4 increases as they age. The same applies to the busbars 5. The size of the overestimation or underestimation of the voltage or resistance values therefore tends to increase with the age of the cells 4. Conventionally, the aging of a cell 4 can be estimated by determining a resistive state ER that is specific thereto. The resistive state ER is obtained by computing the resistance of the cell based on the voltage and the measured current and then by comparing this value with an initial resistance value, corresponding to the resistance of the new cell stored in the memory unit 9 or any other memory element of the vehicle 1, in order to determine a percentage increase in the internal resistance of the cell. This principle is not suitable for the cells 4 connected to a busbar 5 due to the aforementioned disadvantages. According to the present invention, the computation of the resistive state ER is adapted in order to compare the estimated resistance R_{d_est} of the cells 4a connected to a busbar 5 with the initial resistance for the cells 4 connected to a busbar.

The resistive state thus estimated will thus be more representative of the reality of the battery device 2. The resistive state ER also can be used for computing or estimating various operating parameters of the battery device 2, for example, the powers, the method according to the invention thus provides a more reliable evaluation of the state of the battery device 2.

The state of charge, or SOC, of the battery device 2 is also a state parameter of the battery device 2 used in numerous operations of the vehicle 1, such as determining the autonomy, the power or the duration of the charge. Conventionally, the SOC can be estimated by means of a Kalman filter based on the measured voltage and current. As disclosed above, with the voltage measured at the cells 4a connected to a busbar 5 being erroneous, the SOC value will also be erroneous, which generates numerous non-negligible effects relative to the scale of the vehicle 1.

Furthermore, the method 100 according to the invention advantageously can be adapted in order to determine an SOC that is more representative of reality. The step E08 of adjusting and/or determining at least one parameter of the battery device 2 thus can include a sub-step E097 of estimating a state of charge of the various cells 4 of the battery device 2, in which step:
the state of charge of the cells 4b that are not connected to at least one busbar 5 is defined as a function of the measured voltage V_{m_cell} and of the current Iₘ that are specific to them, notably by means of a Kalman filter;
the state of charge of the cells 4a that are connected to at least one busbar 5 is defined as a function of the current that is specific thereto as follows:

$${SOC}_{t} = {SOC}_{t - 1} + \frac{{I}_{m} \times Δ t}{C} \qquad ( 4 )$$

where:
SOCₜ is the state of charge of a cell connected to a busbar 5 at the instant t, Iₘ is the current flowing through the measured cell, C is the capacity of the cell, and Δt is the sampling time, for example, in hours.

The method according to the invention thus can be executed so that, during the step E08 of adjusting and/or determining at least one limiting and/or state parameter of the operation of the battery device 2, all or some of the various aforementioned parameters can be estimated, then associated with at least one operating state of the battery device 2. Said parameters also can be associated with other functions of the battery device 2 and can be transmitted to various systems equipping the vehicle 1, such as systems for locating the vehicle 1 in the road infrastructure or driving assistance systems. According to a preferred embodiment, the various aforementioned parameters are estimated independently of how the vehicle 1 is used when executing the method, in other words, independently of the usage mode, which optionally can be detected when executing the method. The parameters thus estimated relating to a usage mode that is not being executed then can be stored in the memory unit 9, while those relating to a mode being executed can be stored and/or applied directly to the current use.

The method and the system according to the invention thus advantageously allow battery device management that is more adapted to its architecture. This optimizes the durability but also harnesses the performance capabilities of the processing device. Furthermore, the operation of ancillary systems equipping the vehicle and based on parameters relating to the battery device is improved.

However, the present invention is not limited to the means and modes described and illustrated herein and it also extends to any equivalent means or mode and to any technically operative combination of such means insofar as they ultimately fulfil the functionalities described and illustrated in the present document.

1-11. (canceled)

12. A method for managing an electric battery device comprising a plurality of modules mounted in series, each comprising a plurality of cells mounted in series, each module being directly electrically connected to at least one other module of the plurality of modules so as to form a pair of modules, with this connection being made via a busbar connected at a cell of each of the modules of the pair, the management method comprising:
measuring a voltage specific to each cell, whether or not it is connected to a busbar, via slave elements, and measuring the temperature of each module, with each temperature measurement being associated with the one or more busbars connected to the considered module, each slave element comprising a plurality of measurement channels and being connected to the two modules of the considered pair;
measuring a current flowing through the battery device;
transmitting the measurements to a processing unit remote from the battery device;
estimating a voltage compensation value specific to each cell connected to a busbar, the compensation value corresponding to an estimated voltage of the considered busbar for each of said cells, with the compensation value being estimated as a function of the temperature and of the current of the module comprising the considered cell;
estimating a corrected voltage value specific to each of the cells connected to a busbar by compensating the measured voltage value with the estimated compensation value;
adjusting and/or determining at least one limiting and/or state parameter of the operation of the battery device as a function of the estimated corrected voltage and/or as a function of the measured voltage.

13. The management method as claimed in claim 12, wherein the compensation value depends on an estimated resistance (Rest) of the busbar connected to the considered cell, with the estimated resistance being defined as follows:
$${R}_{est} = {R}_{ref} \times ( 1 + {α}_{1} \times ( {T}_{mod} - {T}_{ref} ) ) + {R}_{cont} \times ( 1 + {α}_{2} \times ( {T}_{mod} - {T}_{ref} ) )$$
where:
T_{ref} is a fixed, reference temperature value,
R_{ref} is a fixed value for estimating the resistance of the busbar based on its dimensions and its composition at the reference temperature T_{ref};
T_{mod} is the temperature of the module to which the considered busbar is connected,
R_{cont} is an estimated fixed value of the contact resistance that exists between the considered module and the busbar connected thereto,
α₁ is a fixed value representing the increase in the reference resistance as a function of the temperature, and
α₂ is a fixed value representing the increase in the contact resistance as a function of the temperature.

14. The management method as claimed in claim 13, wherein the determining at least one limiting parameter and/or at least one state parameter comprises:
determining a maximum voltage value specific to a cell from among a set formed by the measured voltage values, for the cells that are not connected to a busbar, and the estimated corrected voltages, for the cells that are connected to at least one busbar, and
determining, as a function of the maximum voltage value, a charging power that can be allocated to the battery device when it is in a charging mode, with the charging power being limited when the maximum voltage value is greater than or equal to a maximum charging voltage threshold, and/or
determining, as a function of the maximum voltage value, a regenerative charging power that can be allocated to the battery device when it is in a regenerative charging state, with the regenerative charging power being limited when the maximum voltage value is greater than or equal to a maximum regenerative charging voltage threshold.

15. The management method as claimed in claim 14, wherein the maximum voltage value Vₘₐₓ is defined as follows:
$${V}_{max} = Max {\{ {V}_{m \_ cell} - {R}_{est} \times {I}_{m} \}}_{i = 1}^{nbr \_ cell}$$
where:
Rₑₛₜ is the estimated resistance of the considered busbar,
V_{m_cell} is the voltage measured for each cell, whether or not it is connected to a busbar,
Iₘ is the current flowing through the battery, and
nbr_cell is the number of cells included in the entire battery device.

16. The management method as claimed in claim 14, further comprising:
determining a usage mode of the electric battery device from among a charging, discharging, or regenerative charging mode; and
regulating, when a charging mode is detected, the charging power comprising:
computing a variation in the charging power between the charging powers respectively observed between two instants tn−1 and tn,
estimating a charging power to be implemented at a future instant tn+1, and detecting a future increase in the charging power with respect to the previously computed power variation and to the charging power observed at the instant tn, and
limiting the future charging power such that, at the instant tn+1, the charging power is limited so as to be less than or equal to the charging power implemented at the instant tn, with the limitation of the charging power being lifted when a temperature variation of at least one module is detected as being greater than a predetermined temperature threshold between the instants tn−1 and tn.

17. The management method as claimed in claim 13, wherein the determining at least one limiting parameter and/or at least one state parameter comprises:
determining a minimum voltage value of a cell from among a set comprising the measured voltage values, for the cells that are not connected to a busbar, and from among the estimated corrected voltages, for the cells that are connected to a busbar, and
determining a discharging power of the battery device as a function of the minimum voltage value, with the discharging power being limited when the minimum voltage value is less than or equal to a minimum discharging voltage threshold.

18. The management method as claimed in claim 17, wherein the minimum voltage value Vₘᵢₙ is defined as follows:
$${V}_{min} = Min {\{ {V}_{{m}_{cell}} - {R}_{est} \times {I}_{m} \}}_{i = 1}^{{nbr}_{cell}}$$
where:
Rₑₛₜ is the estimated resistance of the considered busbar,
V_{m_cell} is the voltage measured for each cell, whether or not it is connected to a busbar,
Iₘ is the current flowing through the battery device,
n_{br_cell} is the number of cells included in the entire battery device.

19. The management method as claimed in claim 17, wherein the determining at least one limiting parameter and/or at least one parameter comprises:
estimating a resistance of each cell connected to a busbar at an instant tx, comprising computing an average resistance of the cells of the battery device that are not connected to a busbar as a function of the voltages measured for these cells and assigning the value of such an average to each cell connected to a busbar, and
determining a discharging power that can be allocated to the battery device when the minimum voltage value is greater than the minimum discharging voltage threshold, with the discharging power being determined as a function of the resistances of the various cells and of the measured temperature for each module.

20. The management method as claimed in claim 12, wherein the determining at least one limiting parameter and/or at least one parameter comprises estimating a state of charge of the various cells of the battery device:
with the state of charge of the cells that are not connected to a busbar being defined as a function of the measured voltage and the current that are specific thereto, and
with the state of charge of the cells that are connected to a busbar being defined as a function of the current specific thereto as follows:
$${SOC}_{t} = {SOC}_{t - 1} + \frac{{I}_{m} \times Δ t}{C}$$
where:
SOCₜ is the state of charge of a cell connected to a busbar at the instant t,
Iₘ is the current flowing through the battery device,
C is the capacity of a cell connected to a busbar, and
Δt is the sampling time.

21. A system for managing an electric battery device comprising a plurality of modules each comprising a plurality of cells, with each module being directly electrically connected to at least one other module of the plurality of modules so as to form a pair of modules, with this connection being made by means of a busbar connected at a cell of each of the modules of the pair, with the various modules being electrically connected to each other, the system comprising hardware and/or software elements configured to implement the management method as claimed in claim 12, the hardware elements comprising at least one slave element configured to take temperature and voltage measurements connected to each of the modules of the pair, a processing unit configured to receive measurements from the at least one slave element, a memory unit, and at least one current sensor.

22. A hybrid or electric motor vehicle comprising:
at least one electric battery device comprising a plurality of modules each comprising a plurality of cells, with each module being electrically connected to each of the other modules of the plurality of modules by a busbar in the vicinity of at least one cell, with the vehicle further being equipped with the management system as claimed in claim 21.
